(19) United States
(12) Patent Application Publication
(10) Pub. No.: US 2014/0002976 A1
(43) Pub. Date: Jan. 2, 2014

(54) RECESSED BOTTOM-ELECTRODE CAPACITORS AND METHODS OF ASSEMBLING SAME

(71) Applicants: Ruth A. Brain, Portland, OR (US); Joseph M. Steigerwald, Forest Grove, OR (US)

(72) Inventors: Ruth A. Brain, Portland, OR (US); Joseph M. Steigerwald, Forest Grove, OR (US)

(21) Appl. No.: 13/997,974

(22) PCT Filed: Nov. 10, 2011
(86) PCT No.: PCT/US11/60113

§ 371 Date: Sep. 18, 2013

(51) Int. Cl. H01L 49/02; H01L 27/108; G06F 1/16

(52) U.S. Cl. CPC H01L 28/40; G06F 1/16; H01L 27/108
USPC 361/679.02; 438/396; 257/532

(57) ABSTRACT

A capacitor-over-bitline structure includes a bottom electrode that has an open vessel form factor. The bottom-electrode form factor includes a floor, rectilinear sidewalls, and a rim that defines the topmost feature. A capacitor dielectric film contacts and covers the floor, the sidewalls, and the rim. A top electrode has a convex form factor that complements the concave bottom-electrode form factor. A process of forming the capacitor-over-bitline structure by spinning on a reflowable sacrificial material such as an oxide that covers both logic and memory portions of a semiconductive device, followed by a polish-back process and a recessing etch of the bottom electrode.

### TECHNICAL FIELD

Disclosed embodiments relate to capacitor cells disposed above source- and drain contacts.

### BRIEF DESCRIPTION OF THE DRAWINGS

In order to understand the manner in which embodiments are obtained, a more particular description of various embodiments briefly described above will be rendered by reference to the appended drawings. These drawings depict embodiments that are not necessarily drawn to scale and are not to be considered to be limiting in scope. Some embodiments will be described and explained with additional specificity and detail through the use of the accompanying drawings in which:

FIG. 1 is a cross-section elevation of capacitor-over-bitline structure for a semiconductive device according to an example embodiment;

FIG. 1a is a cross-section elevation of the capacitor-over-bitline structure depicted in FIG. 1 during processing according to an example embodiment;

FIG. 1b is a cross-section elevation of the capacitor-over-bitline structure depicted in FIG. 1a during further processing according to an example embodiment;

FIG. 1c is a cross-section elevation of the capacitor-over-bitline structure depicted in FIG. 1b during further processing according to an example embodiment;

FIG. 1d is a cross-section elevation of the capacitor-over-bitline structure depicted in FIG. 1c during further processing according to an example embodiment;

FIG. 1e is a cross-section elevation of the capacitor-over-bitline structure depicted in FIG. 1d during further processing according to an example embodiment;

FIG. 1f is a cross-section elevation of the capacitor-over-bitline structure depicted in FIG. 1e during further processing according to an example embodiment;

FIG. 2 is a perspective, partial cut-away of a portion of a capacitor-over-bitline structure according to an example embodiment;

FIG. 3 is a process and method flow diagram according to an example embodiment;

FIG. 4 is a schematic of a computer system according to example embodiments; and

FIG. 5 is a cross-section elevation of the capacitor-over-bitline structure depicted in FIG. 1c during further processing according to an example embodiment.

### DETAILED DESCRIPTION

Processes are disclosed where capacitor-over-bitline (COB) structures are assembled and coupled with microelectronic devices as dynamic random-access memory (DRAM) cells. Fabrication of the bottom electrode is done in a way to resist shorting of the bottom electrode into any top contacts.

Reference will now be made to the drawings wherein like structures may be provided with like suffix reference designations. In order to show the structures of various embodiments more clearly, the drawings included herein are diagrammatic representations of integrated circuit chips assembled with COB structures. Thus, the actual appearance of the fabricated chip substrates, alone or in chip packages, for example in a photomicrograph, may appear different while still incorporating the claimed structures of the illustrated embodiments. Moreover, the drawings may only show the structures useful to understand the illustrated embodiments. Additional structures known in the art may not have been included to maintain the clarity of the drawings.

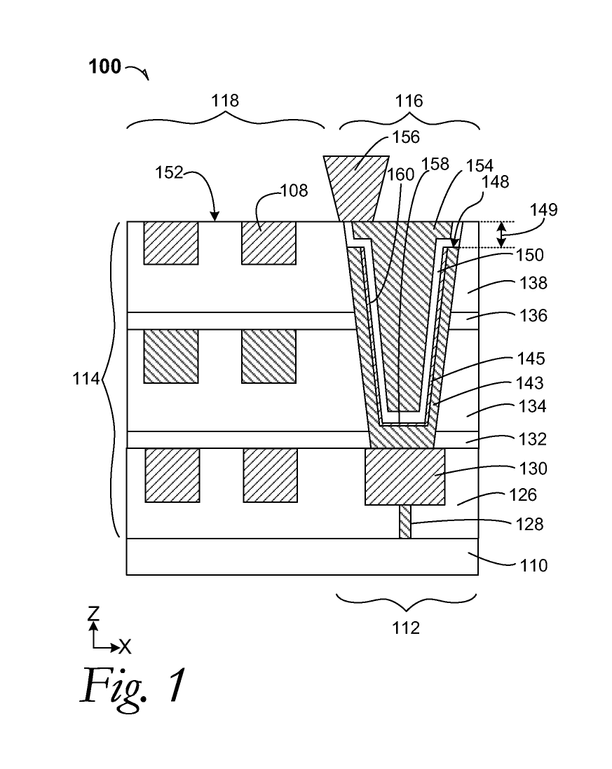

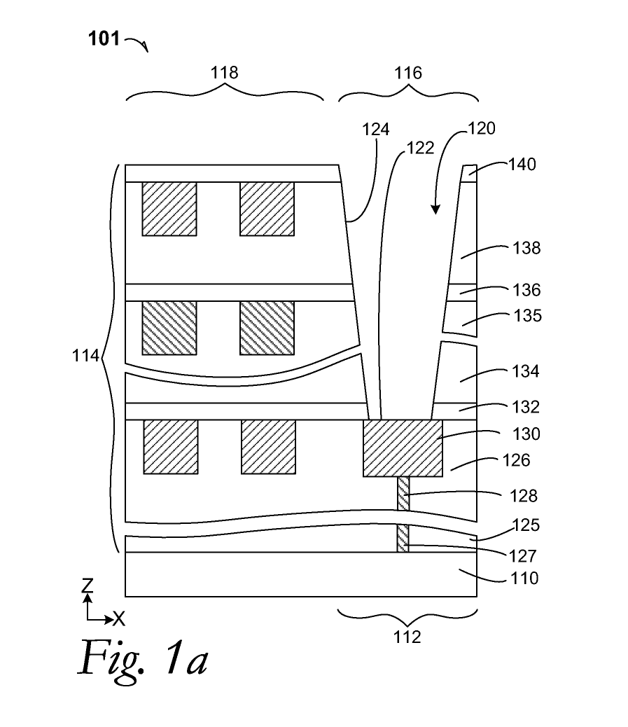

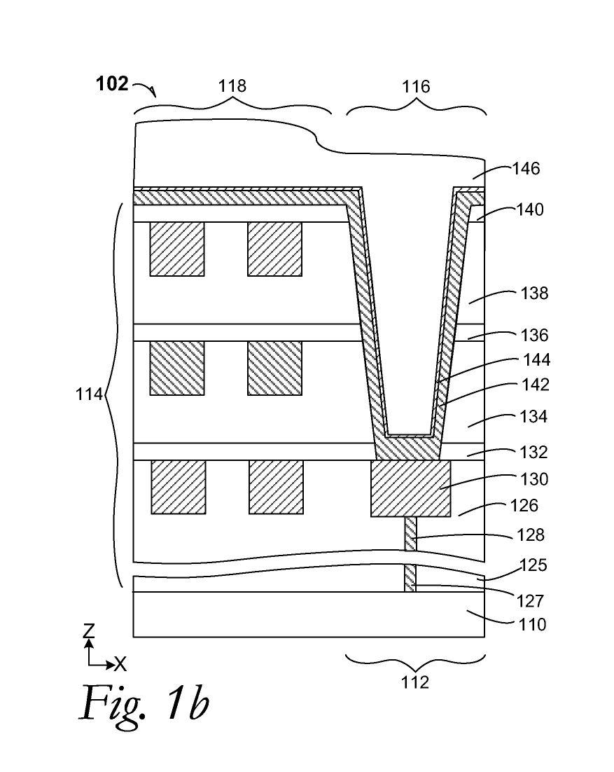

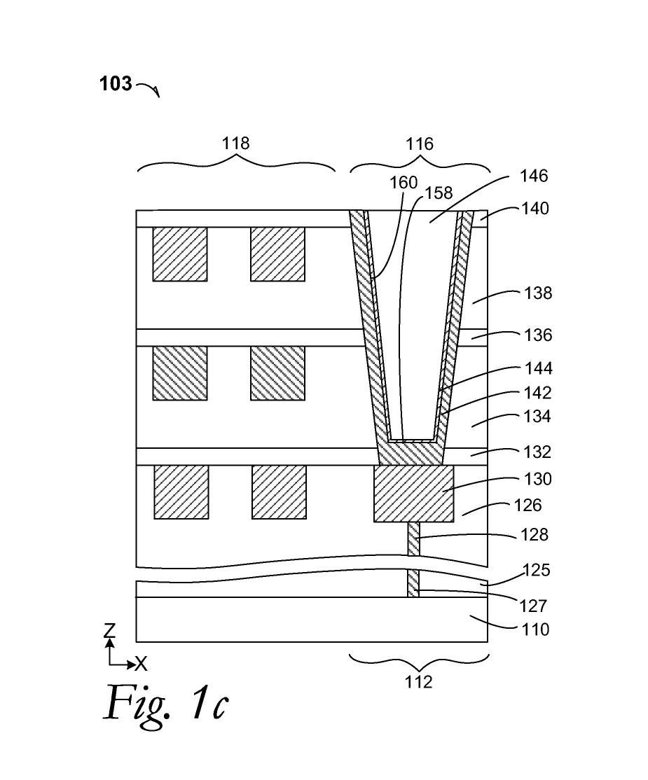

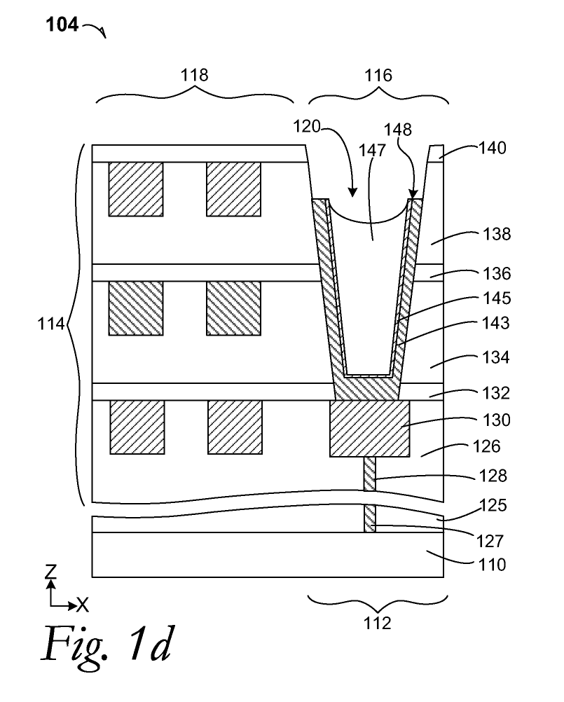

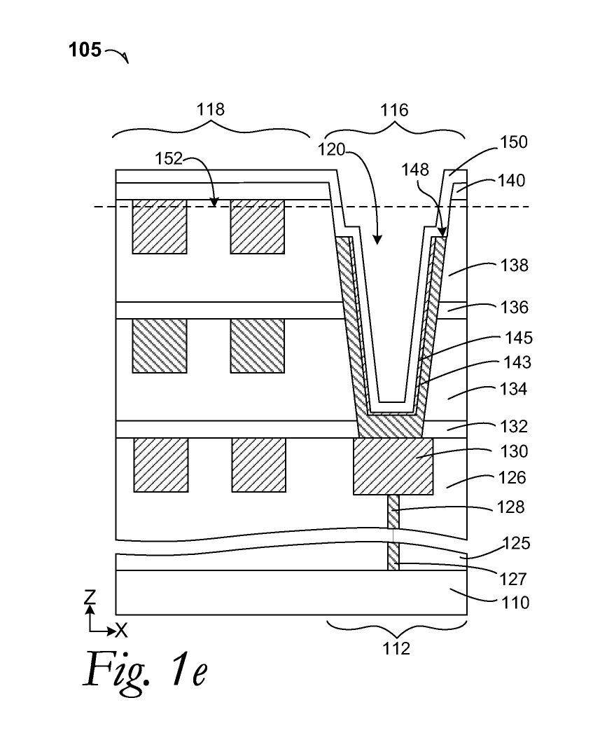

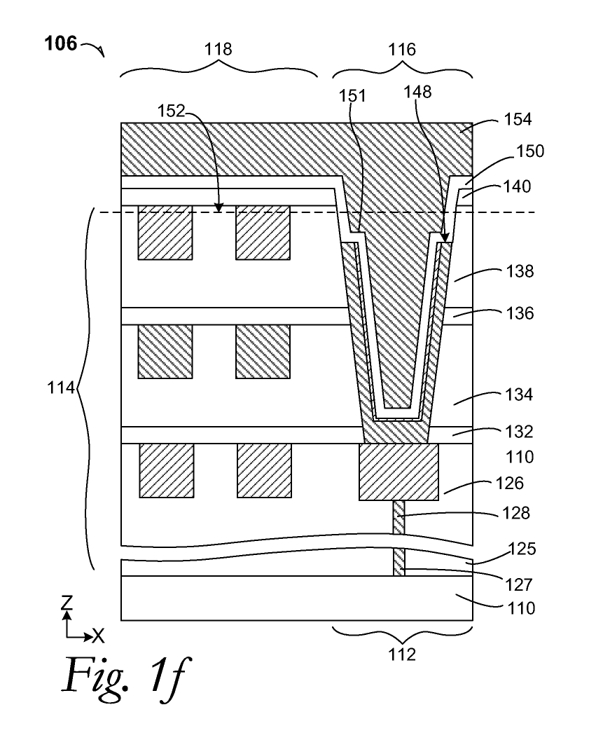

FIG. 1 is a cross-section elevation of a capacitor-over-bitline structure 100 according to an example embodiment. The capacitor-over-bitline (COB) structure 101 includes a semiconductive substrate 110 with a source/drain (S/D) region 112 and a back-end (BE) metallization 114 built above the semiconductive substrate 110. In an embodiment, the semiconductive substrate 110 is semiconductive portion of a processor die such as that made by Intel Corporation of Santa Clara, Calif. The semiconductive substrate 110 may also be referred to as a die although it is understood that the BE metallization is part of the die. The capacitor-over-bitline (COB) structure 100 also shows a memory region 116 and a logic region 118 as being side-by-side. It is understood that the two regions 116 and 118 are illustrated side-by-side for convenience.

The BE metallization 114 may also be referred to as a BE interconnect stack. The BE metallization 114 may include metal layers such as from metal-1 (M1) up to metal-n (Mₙ) such as M12, but not limited to M12 where M1 is adjacent the semiconductive substrate 110. Incidental metallization 108 is shown in the logic region 118. In an embodiment, an upper metallization trace 108 is an M12 metallization. The BE metallization 114 is illustrated in simplified form, but it comprises multiple levels of interconnects that are isolated from one another by multiple layers of interlayer dielectric (ILD) materials.

A first interlayer dielectric (ILD) layer 126 is disposed over the semiconductive substrate 110 and a first etchstop layer 132 caps the first ILD layer 126. As illustrated, a second ILD layer 134 is disposed above the first etchstop layer 132 and a second etchstop layer 136 caps the second ILD layer 134. A subsequent ILD layer 138 is disposed at the top 152 of the BE metallization 114.

The capacitor cell depicted in FIG. 1 includes a bottom electrode 143 that is recessed below a top surface 152 of the BE metallization 114. The bottom electrode 143 includes a floor 158 and sidewalls 160 that an open-vessel form factor. The bottom electrode 143 also has rim 148 that is the topmost (positive Z-direction) feature thereof, and the bottom electrode 143 is electrically insulated by a capacitor dielectric layer 150.

The capacitor dielectric layer 150 also insulates and protects the rim 148 of the bottom electrode 143 from electrical shorting at the top surface 152. Inset depth 149 of the rim 148 may be in a range from zero to 1,000 nanometer (nm).

The bottom electrode 145 has a bottom-electrode barrier 145 that matches the bottom electrode 143 in vertical (positive Z-direction) form factor such that the bottom-electrode barrier 145 is also protected at the rim 148 by the capacitor dielectric layer 150.

A capacitor cell cavity 120 (see FIG. 1a) has been filled with the bottom electrode 143, the bottom-electrode barrier 145 if present, the capacitor dielectric layer 150, and a top electrode 154. The top electrode 154 has a form factor that reflects the rim 148 of the bottom electrode 143. The combination of bottom electrode 143, capacitor dielectric layer 150, and top electrode 154 is referred to as a metal-insulator-metal (MIM) capacitor. The MIM capacitor is a COB configuration where a bitline contact 128 is aligned below (X-direction symmetry) the MIM capacitor.

Further coupling of the capacitor structure at the top electrode 154 is depicted by a top contact 156. It is seen that the top contact 156 contacts the top electrode 154, but it is incidentally misaligned as to lateral (X-direction) symmetry of the capacitor cell. Since the bottom electrode 143, however, is recessed below the top surface 152, the risk of shorting of the bottom electrode 143 into the top contact 156 is reduced. In other words, the top contact 156 aligns with the rim 148, but because the bottom electrode 143 is recessed, it is not shorted into the top contact 156.

In an embodiment, the semiconductive substrate 110 is a semiconductor material such as but not limited to silicon (Si), silicon germanium (SiGe), germanium (Ge), or III-V compound semiconductors. The semiconductive substrate 110 can be monocrystalline, epitaxial crystalline, or polycrystalline. In an embodiment, the semiconductive substrate 110 is a semiconductor hetero structure such as but not limited to a silicon-on-insulator (SOI) substrate, or a multi-layered substrate comprising silicon, silicon germanium, germanium, III-V compound semiconductors, and any combinations thereof. Active devices are located at the active surface and they refer to components such as but not limited to gates, transistors, rectifiers, and isolation structures that form parts of integrated circuits. The active devices are coupled as functional circuits by the BE metallization 114.

FIG. 1a is a cross-section elevation of the capacitor-over-bitline structure depicted in FIG. 1 during processing according to an example embodiment. The COB structure 101 includes the semiconductive substrate 110 with the S/D region 112 and the BE metallization 114 built above the semiconductive substrate 110.

During processing, a capacitor cell cavity 120 is formed in the BE metallization 114 such that a capacitor bottom 122 and a capacitor sidewall 124 are formed. Processing to form the capacitor cell cavity 120 may be done by an etch that stops at a landing pad 130. Other processing may be done such as laser drilling to form the capacitor cell cavity 120. The capacitor cell cavity 120 has been penetrated at the subsequent ILD layer 138 that is topped with the subsequent etchstop layer 140. The capacitor cell cavity 120 in the illustrated embodiment has also penetrated the second ILD layer 134. In the illustrated embodiment, the first ILD layer 126 represents the level of the capacitor bottom 122. The bitline contact 128 is depicted making a coupling to the semiconductive substrate 110 at the S/D region 112. The etch has exposed a landing pad 130 that is in contact with the bitline contact 128 by penetrating the first etchstop layer 132. These several ILD layers are illustrative and the capacitor cell cavity 120 may be formed through several layers of metallization including from penetrating from a top ILD layer all the way down to M1, which usually represents the metallization adjacent and on the silicon of the semiconductive substrate 110. For example, in an M1 to M12 BE metallization structure, the capacitor cell cavity 120 could penetrate all layers beginning with the subsequent layer such as the ILD layer containing M12 and bottoming out at M1. Consequently, the capacitor cell cavity may actually stretch between M1 and M12, where M1 includes the first ILD layer 126 and M12 includes the subsequent ILD layer 138. As such, where the first etchstop layer 132 abuts the second ILD layer 134 a penultimate ILD layer 135 is separated from the second ILD layer 134 by a symbolic break, but the penultimate ILD layer 135 is spaced apart from the subsequent ILD layer 138 only by the etchstop layer 136. For a three-layer BE metallization, the second ILD layer 134 and the penultimate ILD layer 135 are the same layer.

It is also seen that the bitline contact 128 may not be found in the bottom-most ILD layer that abuts the semiconductive material of the semiconductive substrate 110. Consequently, where the ILD first layer 126 represents the layer upon which the capacitor cell cavity 120 reaches a bottom 122, but where the ILD first layer 126 does not abut the semiconductive material of the semiconductive substrate 110, an ILD primary layer 125 abuts the semiconductive substrate 110 and the bitline coupling 128 of the ILD first layer 126 is coupled to a bitline contact 127. A symbolic break separates the ILD primary layer 125 from the ILD first layer 126. For a three-layer BE metallization, however, the ILD primary layer 125 and the ILD first layer 126 are the same layer and the bitline coupling 128 and the bitline contact 127 are the same bitline contact.

Going forward in this disclosure, the BE metallization 114 is represented as a three-layer ILD structure. It is understood, however, that the features and discussed embodiments of FIG. 1a may be incorporated into any of FIGS. 1b-1f as well as FIG. 1 as discussed herein.

FIG. 1b is a cross-section elevation of the capacitor-over-bitline structure depicted in FIG. 1a during further processing according to an example embodiment. The COB structure 102 is being processed such that the bottom electrode 142 has been deposited to cover both the logic region 118 and to fill the capacitor cell cavity in the memory region 116. In an embodiment, the bottom electrode 144 is a copper film that is deposited by chemical vapor deposition (CVD) such that the bottom electrode adheres to the bottom 122 and the sidewalls 124. Other metals may be used to form the bottom electrode 144. Other materials may be used to form the bottom electrode 144. In an embodiment, the bottom electrode is formed by depositing a titanium nitride film 144. Additionally according to an embodiment, a bottom-electrode barrier 144 has been deposited.

Thereafter, a sacrificial fill material 146 has also been blanket deposited. It is seen that the sacrificial fill material 146 has a topology that is thicker (Z-direction) above the logic region 118 than above the memory region 116 because of significant amounts of the sacrificial fill material 146 filling into the capacitor cell cavity 120. In an embodiment, the sacrificial fill material 146 is formed by a spin-on-and fill process with a suitable sacrificial material that has both spin-on and wetting qualities to cover the upper surface of the BE metallization 114 and to wet to the bottom of the capacitor cell cavity 120. In an embodiment, the sacrificial fill material 146 is a spin-on glass oxide. In an embodiment, the sacrificial fill material 146 is formed by a chemical vapor deposition process. In an embodiment, the sacrificial fill material 146 is a selective light-absorbing material (SLAM) that is useful in SLAM polishing processes.

FIG. 1c is a cross-section elevation of the capacitor-over-bitline structure depicted in FIG. 1b during further processing according to an example embodiment. The COB structure 103 has been processed by polishing back the sacrificial fill material 146 such that it has been removed from the logic region 118 as well as superficial areas of the memory region 116. In an embodiment, a SLAM polishing process achieves a polishing stop at the subsequent etchstop layer 140 as well as a surface of the sacrificial fill material 146 that is flush with the subsequent etchstop layer 140. By this polishing process the bottom electrode 142 has been formed in the capacitor-cell cavity to a first height, which is equal to the upper surface of the subsequent etchstop layer 140. The bottom electrode 142 also exhibits the floor 158 and the sidewalls 160, although the sidewalls 160 are to be recessed by further processing.

FIG. 1d is a cross-section elevation of the capacitor-over-bitline structure depicted in FIG. 1c during further processing according to an example embodiment. The COB structure 104 has experienced a sacrificial etch such that the bottom electrode 142 depicted in FIG. 1c has been etched back to form a recessed bottom electrode 143, as well as the bottom-electrode barrier 144 has been etched back to form a recessed bottom-electrode barrier 145. During etchback processing, the sacrificial fill material, depicted in FIG. 1c as item 146, but as item 147 in FIG. 1d, may be dished out due to different etch selectivities of the materials to be recessed. It is seen that etch selectivities of the subsequent ILD layer 138 and the subsequent etchstop layer 140 are greater to not being etched than the etch selectivities of the recessed bottom electrode 143 and the recessed bottom-electrode barrier 145 as well as the sacrificial fill material 147. It is understood that the concave profile is a concave-meniscus qualitative depiction of the results of the wet etch to recess the bottom electrode 143. In an embodiment, a convex profile of the sacrificial material 147 is also a useful convex-meniscus qualitative depiction of a wet-etch embodiment result. In any event, the sacrificial fill material 147 etches at a rate similar to that of the bottom electrode 143. In other words, etch selectivity to leave the subsequent etch stop layer 140 and the subsequent ILD layer 138 results in no significant etching, while the recessed bottom electrode 143 and the sacrificial fill material 147 etch at similar rates.

After the recess etchback process is completed, the capacitor cell cavity 120 exhibits a rim 148 of the recessed bottom electrode 143 that is formed in the subsequent ILD layer 138. The rim 148 of the recessed bottom electrode 143 is below (Z-direction) the level of the subsequent etchstop layer 140 and may be referred to the location of a second height for the recessed bottom electrode 143. Similarly, the rim 148 also defines an upper form factor of the recessed bottom-electrode barrier 145.

FIG. 1e is a cross-section elevation of the capacitor-over-bitline structure depicted in FIG. 1d during further processing according to an example embodiment. The COB structure 105 has been processed to remove the sacrificial fill material 147 (FIG. 1d) such as by a wet-etch rinse. Hereinafter, the recessed bottom electrode 143 will be referred to simply as the bottom electrode 143, and the recessed bottom-electrode barrier 145 will be referred to simply as the bottom-electrode barrier 145.

Materials for the bottom electrode 143 are chosen to achieve a large enough charge to be useful as a capacitor in a dynamic random-access memory (DRAM). In an embodiment, the bottom electrode 143 is made of copper. In an embodiment, the bottom-electrode barrier 145 is a material that assists and adjusts the work function of the bottom electrode 143. In an embodiment, the bottom-electrode barrier 145 is made of a material that resists migration of the capacitor dielectric layer 150 into the bottom electrode 143. In an embodiment, the bottom-electrode barrier 145 is made of tantalum (Ta) that may be sputtered onto the bottom electrode 142 as depicted in FIG. 1b. In an embodiment, the bottom-electrode barrier 145 is tantalum nitride (TaₓN_{y}) where x and y represent stoichiometric or non-stoichiometric ratios according to a given useful application. In an embodiment, the bottom-electrode barrier 145 is an oxide film of the bottom electrode 143. In an embodiment, the bottom-electrode barrier 145 is a deposited oxide film of the bottom electrode 143.

Materials for the capacitor dielectric layer 150 are chosen to achieve a large enough charge between capacitor electrodes to be useful as a capacitor in a DRAM such as an embedded DRAM (eDRAM). In an embodiment, a high-k dielectric (k>6) is used. In an embodiment, a capacitor dielectric material is an oxide. In an embodiment, a capacitor dielectric material is silicon dioxide (SiO₂). In an embodiment, a capacitor dielectric material is a hafnium oxide (HfₓO_{y}) where x and y may be chosen to make up either stoichiometric or non-stoichiometric ratios depending upon a given useful dielectric layer composition. In an embodiment, a capacitor dielectric material is an aluminum oxide (AlₓO_{y}) where x and y may be chosen to make up either stoichiometric or non-stoichiometric ratios depending upon a given useful dielectric layer composition. In an embodiment, a capacitor dielectric material is a lead zirconate titanate (PZT) material is used. In an embodiment, a capacitor dielectric material is a barium strontium titanate (BST) material is used.

After the bottom electrode 143 and the bottom-electrode barrier 145 are recesses and the sacrificial fill material is removed, the capacitor dielectric layer 150 is conformally deposited in the capacitor cell cavity 120 upon the bottom electrode 143 and upon the bottom-electrode barrier 145 if present. Deposition of the capacitor dielectric layer 150 also covers the rim 148 of the bottom electrode 143 to form a shoulder form factor. Similarly if the bottom-electrode barrier 145 is present, the shoulder form factor is affected by the bottom-electrode barrier 145.

A theoretical polish-back level 152 is shown that is above the rim 148 of the bottom electrode 143. Consequently, a large bottom electrode surface is preserved to facilitate DRAM capacitance, but the rim 148 of the bottom electrode 143 is protected and insulated by the capacitor dielectric layer 150. For example, the bottom electrode 143 may extend any range from M1 to M12 for a large, useful capacitor surface area, but shorting into a top-electrode contact is avoided by the rim 148 being recessed and electrically insulated by the capacitor dielectric layer 150.

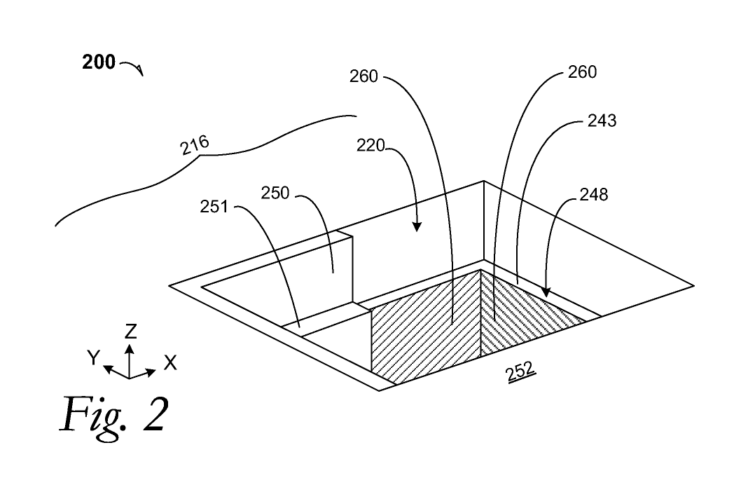

FIG. 2 is a perspective, partial cut-away of a portion of a COB structure 200 according to an example embodiment. Only a memory region 216 is illustrated in part for a single capacitor cell such as for a 1T 1C DRAM cell. Similar to the processing stage depicted in FIG. 1e, the COB structure 200 has experienced an etchback of a bottom electrode 243 such that a rim 248 of the bottom electrode 243 is seen below a theoretical polish-back level 252 in a subsequent ILD layer 238. Further, sacrificial fill material has been removed. Also, a capacitor dielectric layer 250 is conformally deposited in the capacitor cell cavity 220 upon the bottom electrode 243 and the capacitor dielectric layer 250 is mostly cut away to reveal the bottom electrode 243. A bottom-electrode barrier is not illustrated, but it may be present. Deposition of the capacitor dielectric layer 250 also covers the rim 248 of the bottom electrode 243.

In an embodiment, the capacitor cell cavity 220 has a rectilinear form factor when seen in plan view (X-Y plane). As depicted, the bottom electrode 243 is recessed and has right-angle corners spaced apart by planar sidewalls 260, two of which are exposed by cut-away illustration of the capacitor dielectric layer 250. The sidewalls 260 may be described as a plurality of rectilinear sidewalls. Similarly, the capacitor dielectric layer 250 has right-angle corners spaced apart by planar sidewalls, along with a shoulder 251 form factor that seats upon the rim 248 of the recessed bottom electrode 243. Other shapes may be achieved such as a circular form factor when observed in plan view. In an embodiment, the capacitor sidewalls are substantially vertical. In an embodiment, the capacitor sidewalls are less than vertical such that the capacitor-wall perimeter at the rim 248 is larger than the capacitor-wall perimeter at the bottom 122. For example, the capacitor sidewall perimeter depicted in FIG. 1 at the rim 148 is larger than the capacitor sidewall perimeter at the floor 158.

FIG. 1f is a cross-section elevation of the capacitor-over-bitline structure depicted in FIG. 1e during further processing according to an example embodiment. The COB structure 106 has been processed by filling the capacitor cell cavity with a top electrode 154 that seats conformally upon the capacitor dielectric layer 150 including the portion thereof that protects the rim 148 of the bottom electrode 143. Following filling the top electrode 154 into the capacitor cell cavity upon the capacitor dielectric layer 150, polishing back to the theoretical polish-back level 152 may be carried out by known technique. FIG. 1 is a cross-section elevation of the COB structure depicted in FIG. 1f after further processing.

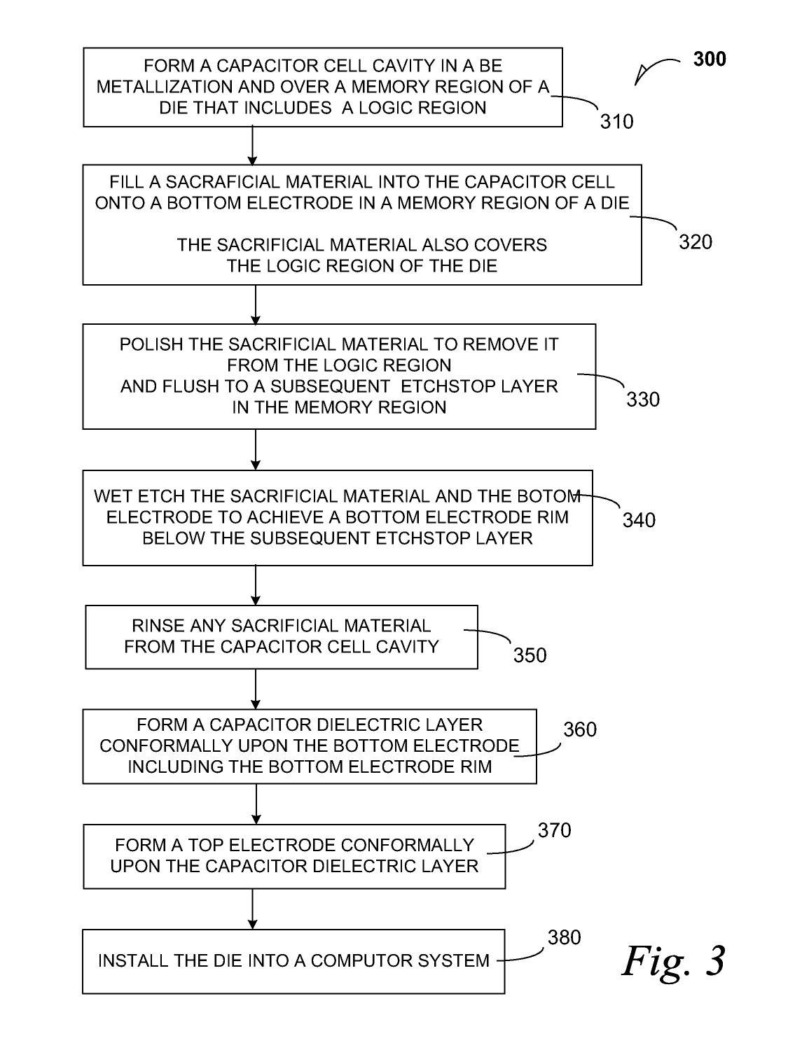

FIG. 3 is a process and method flow diagram 300 according to an example embodiment. Processing is summarized in several stages and is not intended to include exhaustive processing details.

At 310, a process includes forming a capacitor cell cavity in a BE metallization and above a memory region of a die that includes a logic region. In a non-limiting example embodiment, the capacitor cell cavity 120 is etched into the BE metallization 114 that is built above the semiconductive substrate 110 above a bitline contact. The capacitor cell cavity 120 is above a memory region 116 of a semiconductive device 110 that also has a logic region 118.

At 320, the process includes filling a sacrificial material into the capacitor cell cavity to also cover a bottom electrode and also to cover the logic region of the die. In a non-limiting example embodiment, a spinable, reflowable oxide material 146 is formed upon the bottom electrode 142 and the bottom-electrode barrier 144 if present. In an embodiment, the material is a selective light-absorbing material (SLAM) that is useful for polishing back uneven-surfaced configurations such as the topology of the sacrificial material 146 depicted in FIG. 1b.

At 330, the sacrificial fill material is polished back to remove it from the logic region and also from the memory region except for flush with a top etchstop layer and within the capacitor cell cavity. In a non-limiting example embodiment, a SLAM polish process is carried out with mechanical polishing to achieve a configuration of the material 146 as depicted in FIG. 1c.

At 340, the process includes wet etching the sacrificial material and the bottom electrode to achieve a recessed bottom electrode rim that is below the top etchstop layer. In a non-limiting example embodiment, a wet etch has achieved a recessed bottom electrode 143 and a recessed bottom-electrode barrier 145 if present. Results of a wet etch are depicted in FIG. 1d and the sacrificial material 147 exhibits a concave profile while the subsequent etchstop layer 140 and the subsequent ILD layer 138 exhibit an etch selectivity to not being etches. It is understood that the concave profile is a qualitative depiction of the results of a wet etch to recess the bottom electrode 143, and that a convex profile of the sacrificial material 147 is also a useful qualitiative depiction of a wet etch. It is now understood that the wet etch is selective to not removing significant amounts of the subsequent etchstop layer 140 and the subsequent ILD layer 138, but it removes significant amounts of the sacrificial material 146 to expose the bottom electrode 143 to a recessing etch result.

At 350, the process includes rinsing any sacrificial material from the capacitor cell. In a non-limiting example embodiment, sacrificial material 147 is rinsed and removed to leave an exposed bottom electrode with a rim 148.

At 360, the process includes forming a capacitor dielectric layer conformally upon the bottom electrode including upon the bottom electrode rim. In a non-limiting example embodiment, a useful capacitor cell dielectric layer 150 is formed upon the bottom electrode 143 including at the rim 148. This process of recessing the bottom electrode 143 to the height of the rim 148, and covering the bottom electrode 143 also at the rim 148 with the capacitor cell dielectric layer 150 results in a useful bottom electrode that reduces the likelihood of shorting after subsequent processing.

At 370, the process includes forming a top electrode conformally upon the capacitor dielectric layer. In a non-limiting example embodiment, the copper top electrode 154 is filled into the capacitor cell cavity 120, followed by a polishing back operation to the theoretical polish-back level 152. Other processing includes forming a top contact 156 to couple the MIM capacitor cell 100 to the remainder of the die 110.

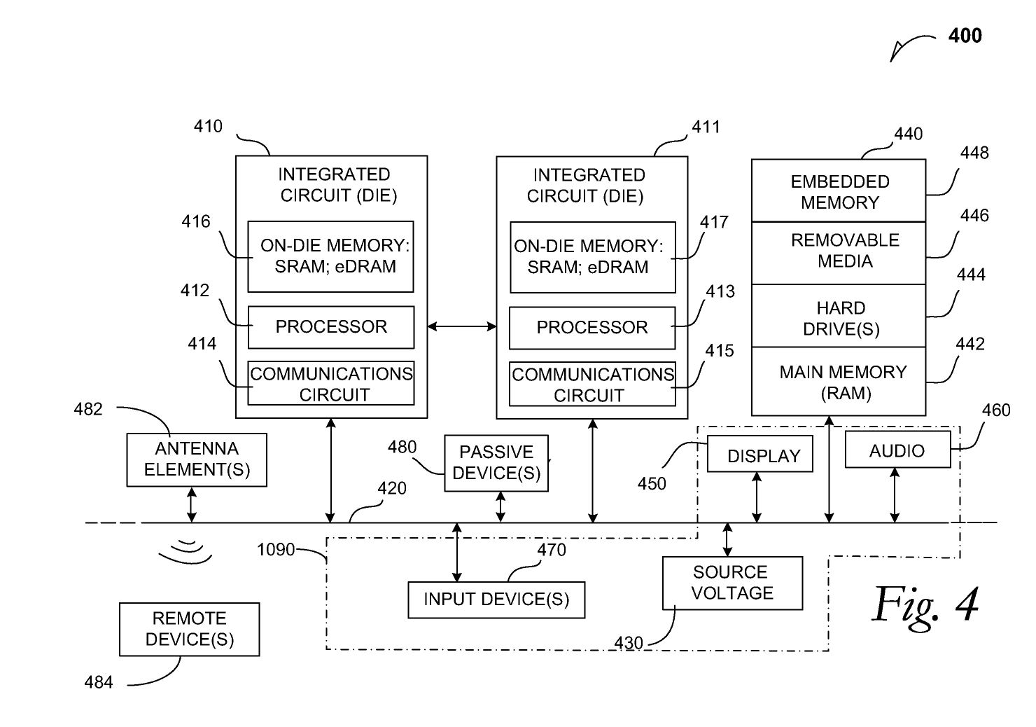

At 380, a method embodiment includes installing the die into a computer system such as a computer system embodiment depicted in FIG. 4.

FIG. 4 is a schematic of a computer system according to an embodiment. The computer system 400 (also referred to as the electronic system 400) as depicted can embody a capacitor-over-bitline according to any of the several disclosed embodiments and their equivalents as set forth in this disclosure. An apparatus that includes a capacitor-over-bitline that is assembled to a computer system.

The computer system 400 may be a smartphone. The computer system 400 may be a tablet computer. The computer system 400 may be a mobile device such as a netbook computer. The computer system 400 may be a desktop computer. The computer system 400 may be integral to an automobile. The computer system 400 may be integral to a television. The computer system 400 may be integral to a DVD player. The computer system 400 may be integral to a digital camcorder.

In an embodiment, the electronic system 400 is a computer system that includes a system bus 420 to electrically couple the various components of the electronic system 400. The system bus 420 is a single bus or any combination of busses according to various embodiments. The electronic system 400 includes a voltage source 430 that provides power to an integrated circuit 410. In some embodiments, the voltage source 430 supplies current to the integrated circuit 410 through the system bus 420.

The integrated circuit 410 is electrically coupled to the system bus 420 and includes any circuit, or combination of circuits according to an embodiment. In an embodiment, the integrated circuit 410 includes a processor 412 that can be of any type of an apparatus that includes a capacitor-over-bitline embodiment. As used herein, the processor 412 may mean any type of circuit such as, but not limited to, a microprocessor, a microcontroller, a graphics processor, a digital signal processor, or another processor. In an embodiment, SRAM embodiments are found in memory caches of the processor 412. Other types of circuits that can be included in the integrated circuit 410 are a custom circuit or an application-specific integrated circuit (ASIC), such as a communications circuit 414 for use in non-equivalent wireless devices such as cellular telephones, smartphones, pagers, portable computers, two-way radios, and other electronic systems. In an embodiment, the processor 410 includes on-die memory 416 such as static random-access memory (SRAM). In an embodiment, the processor 410 includes embedded on-die memory 416 such as embedded dynamic random-access memory (eDRAM). Disclosed COB embodiments and their art-recognized equivalents are integral memory cells in the eDRAM.

In an embodiment, the integrated circuit 410 is complemented with a subsequent integrated circuit 411 such as a graphics processor or a radio-frequency integrated circuit or both as set forth in this disclosure. In an embodiment, the dual integrated circuit 411 includes embedded on-die memory 417 such as eDRAM with any disclosed COB memory cell embodiments. The dual integrated circuit 411 includes an RFIC dual processor 413 and a dual communications circuit 415 and dual on-die memory 417 such as SRAM. In an embodiment, the dual communications circuit 415 is particularly configured for RF processing.

In an embodiment, at least one passive device 480 is coupled to the subsequent integrated circuit 411 such that the integrated circuit 411 and the at least one passive device are part of the any apparatus embodiment that includes a capacitor-over-bitline that includes the integrated circuit 410 and the integrated circuit 411. In an embodiment, the at least one passive device is a sensor such as an accelerometer for a tablet or smartphone.

In an embodiment, the electronic system 400 includes an antenna element 482 such as any capacitor-over-bitline embodiment set forth in this disclosure. By use of the antenna element 482, a remote device 484 such as a television, may be operated remotely through a wireless link by an apparatus embodiment. For example, an application on a smart telephone that operates through a wireless link broadcasts instructions to a television up to about 30 meters distant such as by Bluetooth® technology. In an embodiment, the remote device(s) includes a global positioning system of satellites for which the antenna element(s) are configured as receivers.

In an embodiment, the electronic system 400 also includes an external memory 440 that in turn may include one or more memory elements suitable to the particular application, such as a main memory 442 in the form of RAM, one or more hard drives 444, and/or one or more drives that handle removable media 446, such as diskettes, compact disks (CDs), digital variable disks (DVDs), flash memory drives, and other removable media known in the art. In an embodiment, the external memory 440 is part of a POP package that is stacked upon a capacitor-over-bitline according to any disclosed embodiments. In an embodiment, the external memory 440 is embedded memory 448 such an apparatus that includes a capacitor-over-bitline according to any disclosed embodiment.

In an embodiment, the electronic system 400 also includes a display device 450, and an audio output 460. In an embodiment, the electronic system 400 includes an input device such as a controller 470 that may be a keyboard, mouse, touch pad, keypad, trackball, game controller, microphone, voice-recognition device, or any other input device that inputs information into the electronic system 400. In an embodiment, an input device 470 includes a camera. In an embodiment, an input device 470 includes a digital sound recorder. In an embodiment, an input device 470 includes a camera and a digital sound recorder.

A foundation substrate 490 may be part of the computing system 400. The foundation substrate 490 is a motherboard that supports an apparatus that includes a capacitor-over-bitline embodiment. In an embodiment, the foundation substrate 490 is a board which supports an apparatus that includes a capacitor-over-bitline embodiment. In an embodiment, the foundation substrate 490 incorporates at least one of the functionalities encompassed within the dashed line 490 and is a substrate such as the user shell of a wireless communicator.

As shown herein, the integrated circuit 410 can be implemented in a number of different embodiments, an apparatus that includes a capacitor-over-bitline according to any of the several disclosed embodiments and their equivalents, an electronic system, a computer system, one or more methods of fabricating an integrated circuit, and one or more methods of fabricating and assembling an apparatus that includes a capacitor-over-bitline according to any of the several disclosed embodiments as set forth herein in the various embodiments and their art-recognized equivalents. The elements, materials, geometries, dimensions, and sequence of operations can all be varied to suit particular I/O coupling requirements including capacitor-over-bitline embodiments and their equivalents.

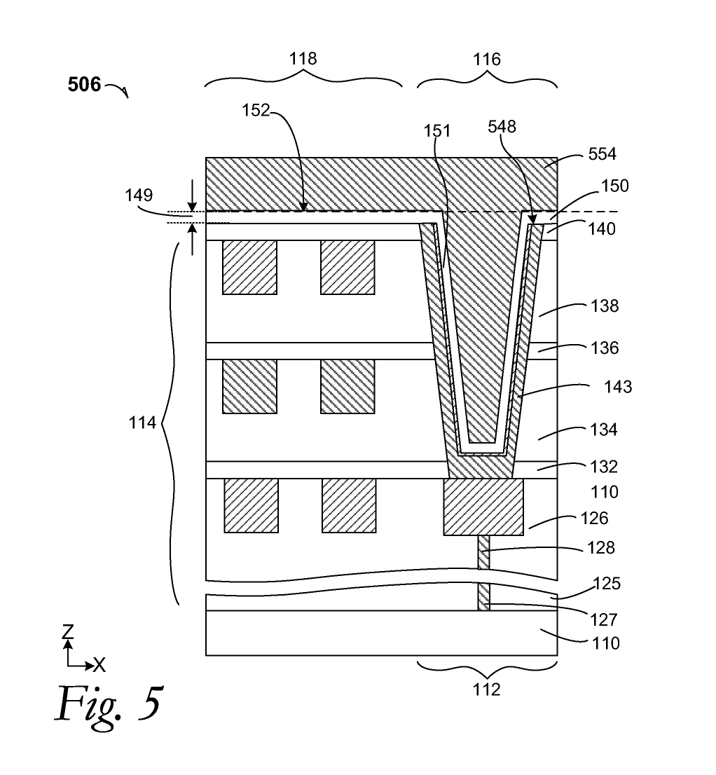

FIG. 5 is a cross-section elevation of the capacitor-over-bitline structure depicted in FIG. 1c during further processing according to an example embodiment.

The COB structure 506 has been processed by polishing back the sacrificial fill material 146 such that it has been removed from the logic region 118 as well as superficial areas of the memory region 116. In an embodiment, a polishing process achieves a polishing stop at the subsequent etchstop layer 140 as well as a surface of the sacrificial fill material 146 that is flush with the subsequent etchstop layer 140. By this polishing process the bottom electrode 142 has been formed in the capacitor-cell cavity to a first height, which is equal to the upper surface of the subsequent etchstop layer 140.

The COB structure 506 has been further processed by rinsing away the sacrificial fill material followed by deposition of the capacitor dielectric layer 150. Thereafter, processing includes filling the capacitor cell cavity with a top electrode 554 that seats conformally upon the capacitor dielectric layer 150 including the portion thereof that protects the rim 548 of the bottom electrode 143. Following filling the top electrode 554 into the capacitor cell cavity upon the capacitor dielectric layer 150, polishing back to the theoretical polish-back level 152 may be carried out by known technique. As a consequence of this processing embodiment, the rim 548 of the bottom electrode 143 is at the same level as the top of the subsequent etchstop layer 140. Further processing may achieve the theoretical polish-back level 152 to move down to match that of the rim 548 of the bottom electrode 143. Inset depth 149 of the rim 548 may be in a range from zero to 1,000 nm depending upon the amount of removal of the capacitor dielectric layer 150. After choosing and achieving the theoretical polish-back level 152, a top contact may be placed in contact with the top electrode 554.

Although a die may refer to a processor chip, an RF chip, an RFIC chip, or a memory chip may be mentioned in the same sentence, but it should not be construed that they are equivalent structures. Reference throughout this disclosure to “one embodiment” or “an embodiment” means that a particular feature, structure, or characteristic described in connection with the embodiment is included in at least one embodiment of the present invention. The appearance of the phrases “in one embodiment” or “in an embodiment” in various places throughout this disclosure are not necessarily all referring to the same embodiment. Furthermore, the particular features, structures, or characteristics may be combined in any suitable manner in one or more embodiments.

Terms such as “upper” and “lower” “above” and “below” may be understood by reference to the illustrated X-Z coordinates, and terms such as “adjacent” may be understood by reference to X-Y coordinates or to non-Z coordinates.

The Abstract is provided to comply with 37 C.F.R. §1.72(b) requiring an abstract that will allow the reader to quickly ascertain the nature and gist of the technical disclosure. It is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate preferred embodiment.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

What is claimed is:

1. A process of forming a capacitor cell above a contact, comprising:
forming a capacitor-cell cavity in an interlayer dielectric (ILD) structure that is disposed above a semiconductive substrate, wherein the capacitor-cell cavity has a bottom and a sidewall, and wherein the semiconductive substrate includes a memory region and a logic region;
forming a bottom electrode in the capacitor-cell cavity to a first height, wherein the bottom electrode couples to a bit-line contact at the capacitor-cell cavity bottom;
filling the capacitor-cell cavity with a sacrificial fill material, wherein the sacrificial fill material also covers the memory region and the logic region;
planarizing the sacrificial fill material to remove it from the logic region;
recessing the bottom electrode from the first height to a second height to form a rim by similarly recessing the sacrificial fill material in the capacitor-cell cavity;
removing remaining sacrificial fill material from the capacitor-cell cavity;
forming a capacitor dielectric layer upon the bottom electrode, wherein the capacitor dielectric layer exhibits a shoulder form factor at the rim;
forming a capacitor top electrode in the capacitor-cell cavity over the capacitor dielectric layer; and
polishing the capacitor top electrode down to a level that is above the rim.

2. The process of claim 1, further including contacting the capacitor top electrode with a top contact at a location that aligns with the rim.

3. The process of claim 1, wherein forming the bottom electrode includes conformally depositing a copper film into the capacitor-cell cavity.

4. The process of claim 1, wherein forming the bottom electrode includes:
conformally depositing a copper film into the capacitor-cell cavity; and
conformally depositing a bottom-electrode barrier onto the copper film, selected from tantalum, tantalum nitride, copper oxide, and a dielectric.

5. The process of claim 1, wherein the sacrificial fill material is a selective light-absorbing material (SLAM) and wherein planarizing the sacrificial fill material includes mechanically polishing to an etchstop layer upon which the sacrificial fill material is disposed, and wherein recessing the bottom electrode to the first height includes etching under conditions that the SLAM etches at a rate similar to that of the bottom electrode.

6. The process of claim 1, wherein recessing the bottom electrode to the first height includes etching under conditions that the sacrificial fill material etches at a rate similar to that of the bottom electrode.

7. The process of claim 1, wherein recessing the bottom electrode to the first height includes etching under conditions that the sacrificial fill material etches at a rate similar to that of the bottom electrode such that the sacrificial fill material forms a concave meniscus in the capacitor cell cavity.

8. The process of claim 1, wherein recessing the bottom electrode to the first height includes etching under conditions that the sacrificial fill material etches at a rate similar to that of the bottom electrode such that the sacrificial fill material forms a convex meniscus in the capacitor cell cavity.

9. A process of forming a capacitor cell above a contact, comprising:
forming a capacitor-cell cavity in an interlayer dielectric (ILD) structure that is disposed above a semiconductive substrate, wherein the capacitor-cell cavity has a bottom and a sidewall, and wherein the semiconductive substrate includes a memory region and a logic region;
forming a bottom electrode in the capacitor-cell cavity to a first height, wherein the bottom electrode couples to a bit-line contact at the capacitor-cell cavity bottom;
recessing the bottom electrode from the first height to a second height to form a rim by similarly recessing a sacrificial fill material that is disposed in the capacitor-cell cavity;
forming a capacitor dielectric layer upon the bottom electrode, wherein the capacitor dielectric layer exhibits a shoulder form factor at the rim; and
forming a capacitor top electrode in the capacitor-cell cavity over the capacitor dielectric layer.

10. The process of claim 9, wherein forming the bottom electrode includes:
conformally depositing a copper film into the capacitor-cell cavity; and
conformally depositing a bottom-electrode barrier onto the copper film, selected from tantalum, tantalum nitride, copper oxide, and a dielectric.

11. The process of claim 9, further including polishing the top electrode to a theoretical level that is above the rim.

12. The process of claim 9, further including:
polishing the top electrode to a theoretical level that is above the rim; and
contacting the capacitor top electrode with a top contact at a location that aligns with the rim.

13. The process of claim 9, wherein the sacrificial fill material is formed onto the bottom electrode and over both a memory region and a logic region of the semiconductive substrate, the process further including polishing the sacrificial fill material to leave substantially material only in the capacitor-cell cavity.

14. The process of claim 9, wherein the sacrificial fill material is formed onto the bottom electrode and over both a memory region and a logic region of the semiconductive substrate, the process further including:
polishing the sacrificial fill material to leave substantially material only in the capacitor-cell cavity; and after forming the capacitor top electrode
polishing the top electrode to a theoretical level that is above the rim; and
contacting the capacitor top electrode with a top contact at a location that aligns with the rim.

15. A capacitor-over-bitline (COB) apparatus, comprising:
a bottom electrode disposed in a back-end (BE) metallization that is disposed above a semiconductive substrate, wherein the bottom electrode has an open-vessel form factor with a floor and a plurality of rectilinear sidewalls;
a bitline contact that contacts the semiconductive substrate at a source/drain (S/D) area, wherein the bitline contact is coupled to the bottom electrode;
a capacitor dielectric layer disposed over the floor, sidewalls, and rim of the bottom electrode, and further disposed upon a subsequent interlayer dielectric (ILD) layer to a top of the BE metallization, and wherein the rim of the bottom electrode terminates below the top of the BE metallization; and
a top electrode disposed upon the capacitor dielectric layer, wherein the top electrode exhibits a form factor that reflects the rim of the bottom electrode.

16. The COB apparatus of claim 15, wherein the bitline contact contacts the bottom electrode at the floor.

17. The COB apparatus of claim 15, wherein the bitline contact is coupled to a bitline coupling that contacts the floor.

18. The COB apparatus of claim 15, wherein the BE metallization includes metal-1 (M1) disposed upon the semiconductive substrate, wherein the rim is disposed in an Mnth ILD layer where n is equal to a number between 2 and 12, and wherein the nth ILD layer is the top of the BE metallization.

19. The COB apparatus of claim 15, wherein the BE metallization includes metal-1 (M1) disposed upon the semiconductive substrate, and wherein the bottom electrode floor is disposed in an ILD layer above M1.

20. The COB apparatus of claim 15, further including a bottom-electrode barrier that is disposed on the bottom electrode floor and sidewalls, wherein the bottom-electrode barrier has a form factor that matches that of the bottom electrode.

21. (canceled)

22. The COB apparatus of claim 15, further including a bottom-electrode barrier that is disposed on the bottom electrode floor and sidewalls, wherein the bottom-electrode barrier has a form factor that matches that of the bottom electrode, wherein the capacitor dielectric layer is disposed upon the bottom-electrode barrier at the floor and sidewalls, and upon the rim of the bottom electrode, and wherein the capacitor dielectric layer is disposed on the rim of the bottom electrode.

23. The COB apparatus of claim 15, wherein the capacitor dielectric layer is disposed over the bottom-electrode at the floor and sidewalls, and upon the rim of the bottom electrode, and wherein the capacitor dielectric layer that is disposed on the rim of the bottom electrode has a rim-parallel surface that is below the top of the BE metallization.

24. The COB apparatus of claim 15, wherein the capacitor dielectric layer is disposed over the bottom-electrode at the floor and sidewalls, and upon the rim of the bottom electrode, wherein the capacitor dielectric layer that is disposed on the rim of the bottom electrode also terminates below the top of the BE metallization, and wherein the capacitor dielectric layer terminates at the top of the BE metallization.

25. A computer system comprising:
a bottom electrode disposed in a back-end (BE) metallization that is disposed above a semiconductive substrate of a die, wherein the bottom electrode has an open-vessel form factor with a floor and a plurality of rectilinear sidewalls;
a bottom-electrode barrier disposed upon the bottom electrode;
a bitline contact that contacts the semiconductive substrate at a source/drain (S/D) area, wherein the bitline contact is coupled to the bottom electrode;
a capacitor dielectric layer disposed over the floor, sidewalls, and upon the rim of the bottom electrode, and further disposed upon a subsequent interlayer dielectric (ILD) layer to a top of the BE metallization, and wherein the rim of the bottom electrode terminates below the top of the BE metallization; and
a top electrode disposed upon the capacitor dielectric layer, wherein the top electrode exhibits a form factor that reflects the rim of the bottom electrode; and a foundation substrate that supports the semiconductive substrate.

26. The computer system of claim 25, wherein the foundation substrate is part of a device selected from the group consisting of mobile device, a smartphone device, a tablet computer device, a vehicle, and a television.
